(19) United States
(12) Patent Application Publication
(10) Pub. No.: US 2025/0199918 A1
(43) Pub. Date: Jun. 19, 2025

(54) NON-TRANSITORY COMPUTER READABLE MEDIUM, CO-SIMULATION METHOD, AND CO-SIMULATION APPARATUS

(71) Applicant: Renesas Electronics Corporation, Tokyo (JP)

(72) Inventors: Ryosuke MOGI, Tokyo (JP); Eiichi ARAI, Tokyo (JP)

(21) Appl. No.: 18/926,494

(22) Filed: Oct. 25, 2024

(30) Foreign Application Priority Data
Dec. 13, 2023 (JP) 2023-210173

(51) Int. Cl. G06F 11/14; G06F 11/34

(52) U.S. Cl. CPC G06F 11/1469; G06F 11/3457

(57) ABSTRACT

A non-transitory computer readable medium stores a program for causing a co-simulation apparatus including a first simulator, a second simulator, a first communication path, and a second communication path to execute a co-simulation method. The first simulator stores first data in a first shared memory via the first communication path. In addition, the first simulator divides information related to a first address of the first shared memory in which the first data is stored into pieces of a size defined by an FMI standard, and transmits the pieces of information to the second simulator via the second communication path. The second simulator reads the first data stored in the shared memory by using the first address via the first communication path.

### CROSS-REFERENCE TO RELATED APPLICATIONS

The disclosure of Japanese Patent Application No. 2023-210173 filed on Dec. 13, 2023 including the specification, drawings and abstract is incorporated herein by reference in its entirety.

### BACKGROUND

This disclosure relates to, for example, a non-transitory computer readable medium storing a program, a co-simulation method, and a co-simulation apparatus.

The number of mounted in-vehicle electronic control units (ECUs) has been increasing year by year, and an increase in development man-hours and an increase in a development period have become problems. In the development of the in-vehicle ECU, attention has been paid to a method for clarifying problems such as design defects and performance shortage at an early stage and reducing rework by performing verification by a computer simulation.

There are disclosed techniques listed below.

### [Patent Document 1] Japanese Unexamined Patent Application Publication No. 2023-012395

In the development of the in-vehicle ECU using the computer simulation, a co-simulation is performed in which a plurality of different simulation tools are connected to simultaneously execute a plurality of simulation processes. Patent Document 1 discloses a virtual development environment device in which a computer aided engineering (CAE) tool and a virtual ECU simulation tool are connected as an example of a co-simulation apparatus that executes such a co-simulation. The CAE tool performs a simulation by using a model in the loop simulation (MILS) model. The virtual ECU simulation tool performs a simulation by using a virtual device model of the ECU to be developed.

### SUMMARY

When the co-simulation is executed, a mechanism (connection bridge) for exchanging a simulation model between the different tools is required. As the connection bridge, for example, a functional mock-up interface (FMI) standard capable of connecting the simulation model without depending on a tool can be adopted. In the connection bridge conforming to the FMI standard, a frame (communication data) of a communication protocol is divided into pieces of a size defined by the FMI standard, and the divided frames are connected by socket communication. In a case where a frame of one communication protocol is large, the number of divisions of the frame increases accordingly. When the number of divisions of the frame increases, it becomes necessary to prepare many connection lines for transmitting the data, and the development man-hours of the connection bridge increase.

Other problems and novel features will be apparent from the description of the present specification and the accompanying drawings.

A non-transitory computer readable medium according to an embodiment stores a program for causing a co-simulation apparatus including a first simulator, a second simulator, a first communication path, and a second communication path to execute a co-simulation method. The first simulator stores first data in a first shared memory via the first communication path. In addition, the first simulator divides information related to a first address of the first shared memory in which the first data is stored into pieces of a size defined by an FMI standard, and transmits the information to the second simulator via the second communication path. The second simulator reads the first data stored in the first shared memory by using the first address via the first communication path.

According to the embodiment, between the first simulator and the second simulator, data used in a co-simulation is transmitted and received using the first communication path via the first shared memory, and the information related to the address of the first shared memory is transmitted and received using the second communication path via a connection bridge conforming to the FMI standard. As a result, an amount of data transmitted using the communication path via the connection bridge conforming to the FMI standard can be reduced. That is, since a number of data connection lines in the connection bridge conforming to the FMI standard can be reduced, an increase in the development man-hours for constructing a co-simulation environment can be suppressed.

### BRIEF DESCRIPTION OF THE DRAWINGS

FIG. 1 is a block diagram illustrating an example of a configuration of a co-simulation apparatus according to a first embodiment.

FIG. 2 is a block diagram illustrating a hardware configuration example of the co-simulation apparatus according to the first embodiment.

FIG. 3 is a sequence diagram illustrating an example of processing of the co-simulation apparatus according to the first embodiment.

FIG. 4 is a block diagram illustrating an example of a configuration of a co-simulation apparatus according to a modification of the first embodiment.

FIG. 5 is a block diagram illustrating an example of a configuration of a co-simulation apparatus according to a second embodiment.

FIG. 6 is a sequence diagram illustrating an example of processing of the co-simulation apparatus according to the second embodiment.

### DETAILED DESCRIPTION

This disclosure will be described with reference to several exemplary embodiments. It is to be understood that these embodiments have been described for the purpose of illustration only and will aid those skilled in the art in understanding and performing this disclosure without suggesting limitations as to the scope of this disclosure. The disclosure described herein is implemented in various methods other than those described below.

In the following description and claims, unless defined otherwise, all technical and scientific terms used herein have the same meaning as commonly understood by those skilled in the art to which this disclosure belongs.

Hereinafter, embodiments of this disclosure will be described with reference to the drawings. Each drawing is merely an example for describing one or more embodiments. Each drawing is not associated with only one particular embodiment, but may be associated with one or more other embodiments. As those skilled in the art will appreciate, various features or steps described with reference to any one of the drawings may be combined with features or steps shown in one or more other drawings, for example, to create an embodiment not explicitly shown or described. All of the features or steps shown in any one of the drawings for describing exemplary embodiments are not necessarily essential, and some features or steps may be omitted. The order of the steps described in any of the drawings may be changed as appropriate.

### First Embodiment

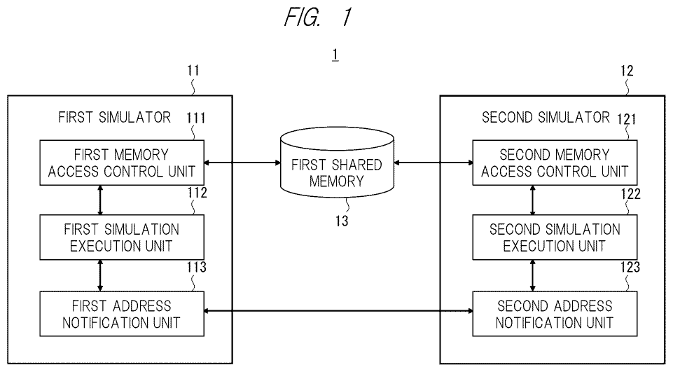

An example of a configuration of a co-simulation apparatus 1 according to a first embodiment will be described with reference to FIG. 1. FIG. 1 is a block diagram illustrating an example of a configuration of the co-simulation apparatus 1 according to the first embodiment. The co-simulation apparatus 1 has a first simulator 11, a second simulator 12, and a first shared memory 13.

The first simulator 11 and the second simulator 12 are implemented by a single computer. Each of the first simulator 11 and the second simulator 12 may be implemented as different processes (instances (of each program) operating on a single computer.

For example, the first simulator 11 may instruct a specific simulation to the second simulator 12 and perform a simulation using a result of the simulation. In this case, for example, the first simulator 11 may perform the simulation based on an instruction by an operator of the co-simulation apparatus 1, and may input data generated by the simulation to the second simulator 12. Then, the second simulator 12 may simulate processing of a specific in-vehicle device based on the data generated by the first simulator 11, and may input data that is a simulation result to the first simulator 11. Note that the first simulator 11 may be referred to as a master simulator, and the second simulator 12 may be referred to as a slave simulator or the like.

The first simulator 11 and the second simulator 12 may be simulators using different methods intended to be used in different development stages. As a result, for example, the simulators using different methods can be operated in cooperation.

In this case, the first simulator 11 may be, for example, an execution environment of MILS, and the second simulator 12 may be, for example, an execution environment of simulator based processor in the loop simulation (SPILS), software in the loop simulation (SILS), or hardware in the loop simulation (HILS).

Note that the MILS may be, for example, a method for performing a simulation by connecting an ECU model and a model of a plant (for example, a control target such as an engine or a motor). The SPILS may be, for example, a simulation method for verifying an actual code (software) of a microcontroller using a model (virtual microcomputer) of a target processor (microcontroller). The SILS may be, for example, a method for performing a simulation by connecting a controller model described in a programming language such as C language and the model of the plant. The HILS may be, for example, a method for performing a simulation by connecting the ECU of the actual machine and the model of the plant.

Furthermore, the first simulator 11 may be, for example, an execution environment of the SILS, and the second simulator 12 may be, for example, an execution environment of the processor in the loop simulation (PILS). Note that the PILS may be, for example, a simulation using a processor (microcontroller) to be implemented.

The first shared memory 13 is an area that can be accessed by a plurality of processes in the memory of the computer. Data stored in the first shared memory 13 may be transferred between the processes using, for example, an application programming interface (API) provided by an operating system (OS) or the like.

The co-simulation apparatus 1 according to the first embodiment enables execution of a co-simulation by transmitting and receiving data between the first simulator 11 and the second simulator 12 by using two communication paths (first communication path and second communication path). The first communication path is a communication path that connects the first simulator 11 and the second simulator 12 via the first shared memory 13. The data communication between the first simulator 11 and the second simulator 12 using the first communication path is performed by one simulator writing data to be transmitted to the other simulator to the first shared memory 13 and the other simulator reading the data written to the first shared memory.

On the other hand, the second communication path is a communication path that connects the first simulator 11 and the second simulator 12 by socket communication. The data communication between the first simulator 11 and the second simulator 12 using the second communication path is performed by one simulator pouring data into a socket and the other simulator receiving the data via the socket. The data transmitted using the second communication path is converted into data defined in the FMI standard and then transmitted. As described above, the second communication path is a communication path via the connection bridge conforming to the FMI standard.

A first memory access control unit 111 and a second memory access control unit 121 write or read the data used in the co-simulation to or from the first shared memory 13. The first communication path described above is a communication path that connects the first simulator 11 and the second simulator 12 via the first shared memory 13. That is, a communication path connecting the first memory access control unit 111 and the second memory access control unit 121 via the first shared memory 13 corresponds to the first communication path.

A first simulation execution unit 112 and a second simulation execution unit 122 are implemented by different simulation tools, and execute different simulations. In the co-simulation apparatus 1, since a co-simulation in which the first simulator 11 and the second simulator 12 operate in cooperation is executed, the first simulator 11 and the second simulator 12 transmit and receive data used in the co-simulation.

Specifically, the first simulation execution unit 112 of the first simulator 11 receives data from the second simulator 12 via the first shared memory 13, and executes a simulation using the data. In addition, the first simulation execution unit 112 generates data by executing a simulation, and stores the generated data in the first shared memory 13 via the first memory access control unit 111 so that the data can be used in the simulation executed by the second simulator 12.

The second simulation execution unit 122 of the second simulator 12 receives data from the first simulator 11 via the first shared memory 13, and executes a simulation by using the data. In addition, the second simulation execution unit 122 generates data by executing the simulation, and stores the generated data in the first shared memory 13 via the second memory access control unit 121 so that the data can be used in the simulation executed by the first simulator 11.

A first address notification unit 113 and a second address notification unit 123 transmit and receive a notification including information related to an address (memory address) of the first shared memory 13 in which the data used in the co-simulation is stored. As described above, transfer of the data used in the co-simulation between the first simulator 11 and the second simulator 12 is implemented by storing data in the first shared memory 13 on the first communication path. At this time, a simulator on a reception side cannot appropriately read the data from the first shared memory 13 unless the simulator on the reception side grasps a position of the first shared memory 13 in which the data to be transferred is stored. Therefore, a simulator on a transmission side transmits information related to the address of the first shared memory 13 in which the data to be transferred is stored to the simulator on the reception side.

The second communication path connecting the first simulator 11 and the second simulator 12 by socket communication corresponds to a communication path between the first address notification unit 113 and the second address notification unit 123. In a case where the information related to the address of the first shared memory 13 is transmitted and received using the second communication path, an address notification unit on the transmission side divides the information related to the address into pieces of a size defined by the FMI standard, and transmits the divided pieces of information related to the address to an address notification unit on the reception side by socket communication. The address notification unit on the reception side receives the information related to the address divided into pieces of the size defined by the FMI standard by socket communication, combines the divided pieces of information related to the address, and restores the information related to the address of the first shared memory 13. The simulator including the address notification unit on the reception side can acquire the data stored in the first shared memory 13 by using the restored information related to the address.

Note that the address notification unit on the transmission side acquires the information related to the address of the first shared memory 13 to be transmitted from the simulation execution unit of the simulator on the transmission side, but may acquire the information from a memory access control unit of the simulator on the transmission side. Furthermore, the address notification unit on the reception side outputs the restored information related to the address of the first shared memory 13 to the simulation execution unit of the simulator on the reception side, but may output the information to a memory access control unit of the simulator on the reception side.

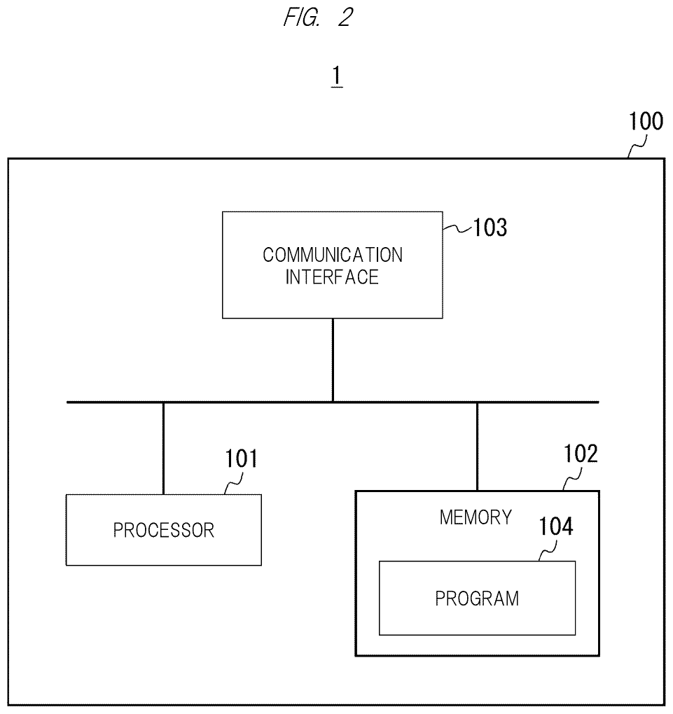

FIG. 2 is a block diagram illustrating a hardware configuration example of the co-simulation apparatus 1 according to the first embodiment. In the example of FIG. 2, the co-simulation apparatus 1 includes a computer including a processor 101, a memory 102, and a communication interface 103. The memory 102 stores at least a part of a program 104. The communication interface 103 includes an interface necessary for communication with other network elements.

When the program 104 is executed by cooperation of the processor 101 and the memory 102, at least a part of the processing of the first embodiment is performed by the co-simulation apparatus 1. For example, the first simulator 11 and the second simulator 12 illustrated in FIG. 1 may be implemented by the processor 101 reading and executing one or more programs stored in the memory 102. The memory 102 may be of any type. The memory 102 may be a non-transitory computer-readable storage medium, as a non-limiting example. The memory 102 may also be implemented by using any suitable data storage technology, such as a semiconductor-based memory device, a magnetic memory device, an optical memory device, a fixed memory, and a removable memory. Although only one memory 102 is illustrated in the co-simulation apparatus 1, some physically different memory modules may exist in the co-simulation apparatus 1. The processor 101 may be of any type. The processor 101 may include one or more of a microprocessor, a digital signal processor (DSP), and a processor based on a multi-core processor architecture as non-limiting examples.

The program includes a command group (or software code) for causing a computer to perform one or more functions described in the first embodiment when being read by the computer. The program may be stored in a non-transitory computer readable medium or a tangible storage medium. By way of example, and not limitation, computer-readable media or tangible storage media include a random-access memory (RAM), a read-only memory (ROM), a flash memory, a solid-state drive (SSD), or other memory technology, a compact disc (CD)-ROM, a digital versatile disc (DVD), Blu-ray (registered trademark) disc, or other optical disk storage, magnetic cassettes, a magnetic tape, a magnetic disk storage, or other magnetic storage devices. The program may be transmitted on a transitory computer-readable medium or a communication medium. By way of example, and not limitation, transitory computer-readable or communication media include electrical, optical, acoustic, or other forms of propagated signals.

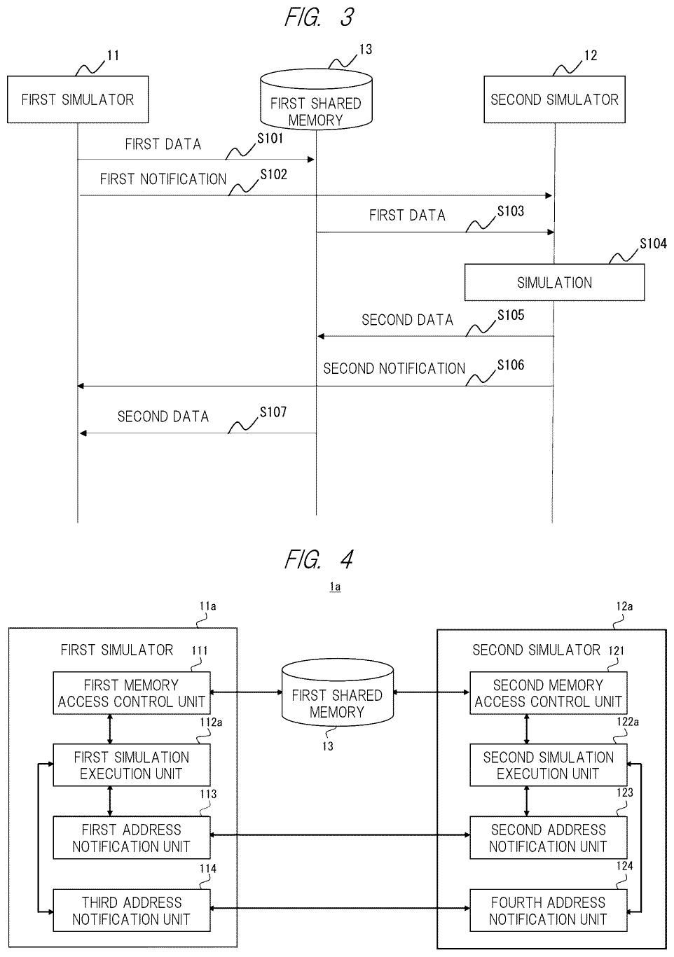

Next, the processing of the co-simulation apparatus 1 according to the first embodiment will be described with reference to FIG. 3. FIG. 3 is a sequence diagram illustrating an example of the processing of the co-simulation apparatus 1 according to the first embodiment. Note that FIG. 3 illustrates processing in which the second simulator 12 performs a simulation by using data provided from the first simulator 11 in a co-simulation in which the first simulator 11 and the second simulator 12 operate in cooperation.

First, in step S101, the first memory access control unit 111 of the first simulator 11 stores first data, which is data in a format according to a specific communication standard, in the first shared memory 13. Here, the first data may be, for example, data generated by a simulation by the first simulation execution unit 112 of the first simulator 11.

The format according to the specific communication standard may be, for example, a frame format determined in communication between the first simulator 11 and the second simulator 12. In the format, for example, what data is included in each byte in the frame may be defined. Furthermore, the specific communication standard may include, for example, controller area network (CAN), Ethernet (registered trademark), CAN with Flexible Data Rate (CAN FD), and FlexRay (registered trademark). As a result, for example, data such as a CAN frame or an Ethernet frame is stored in the first shared memory 13.

Subsequently, the first address notification unit 113 of the first simulator 11 acquires, from the first simulation execution unit 112, information related to a first address of the first shared memory 13 in which the first data is stored. The first address notification unit 113 divides the information related to the first address of the first shared memory 13 into pieces of a size defined by an FMI standard. The first address notification unit 113 transmits a first notification including the divided pieces of information related to the first address of the first shared memory 13 to the second address notification unit 123 of the second simulator 12 (step S102). Here, for example, the information related to the first address may be a head address of the first data in the first shared memory 13.

As described above, the communication path between the first address notification unit 113 and the second address notification unit 123 is the second communication path via the connection bridge conforming to the FMI standard. The first address notification unit 113 transmits the first notification to the second address notification unit 123 by socket communication which is a method for interprocess communication by using the second communication path via the connection bridge conforming to the FMI standard.

The first notification includes first communication standard information indicating a specific communication standard to which the first data conforms, in addition to the information related to the first address. However, in a case where a communication standard of the first data is determined in advance between the first simulator 11 and the second simulator 12, it is not necessary to include the first communication standard information in the first notification. In a case where the first communication standard information is included in the first notification, the first address notification unit 113 divides the first communication standard information into pieces of a size defined by the FMI standard similarly to the information related to the first address, and includes the divided pieces of first communication standard information in the first notification.

Subsequently, the second address notification unit 123 of the second simulator 12 receives the first notification by socket communication. The second address notification unit 123 combines the information related to the first address and the first communication standard information divided into pieces of the size defined by the FMI standard included in the first notification, and restores the information related to the first address and the first communication standard information. The second address notification unit 123 outputs the restored information related to the first address and the first communication standard information to the second simulation execution unit 122.

Subsequently, the second simulation execution unit 122 of the second simulator 12 receives the information related to the first address and the first communication standard information from the second address notification unit 123. The second simulation execution unit 122 determines a communication standard of the first data based on the first communication standard information. As a result, the second simulation execution unit 122 grasps a format according to the communication standard of the first data, that is, a data format of a communication frame related to the first data. The second simulation execution unit 122 outputs the information related to the first address and information on the format according to the communication standard of the first data to the second memory access control unit 121.

Subsequently, the second memory access control unit 121 of the second simulator 12 receives the information related to the first address and the information on the format according to the communication standard of the first data from the second simulation execution unit 122. The second memory access control unit 121 reads the first data from the first shared memory 13 based on the information related to the first address and the information on the format according to the communication standard of the first data (step S103). For example, when the information related to the first address includes a head address of the first data and the information on the format according to the communication standard of the first data includes information related to a size of the first data, the second memory access control unit 121 can read data corresponding to the size of the first data from the head address of the first data from the first shared memory 13. In this way, the second simulator 12 acquires the first data from the first simulator 11 by using the first communication path including the first shared memory 13. In addition, the second memory access control unit 121 outputs the read first data to the second simulation execution unit 122.

Subsequently, the second simulation execution unit 122 of the second simulator 12 performs a simulation based on the first data (step S104). The second simulation execution unit 122 generates second data conforming to a specific communication standard as a simulation result. Here, a communication standard of the second data may be the same as the communication standard to which the first data conforms. The second simulation execution unit 122 outputs the generated second data to the second memory access control unit 121.

Subsequently, the second memory access control unit 121 of the second simulator 12 stores the second data in a format according to a specific communication standard in the first shared memory 13 (step S105). As a result, for example, frame data of a response to the CAN frame, the Ethernet frame, or the like transmitted from the first simulator 11 is stored in the first shared memory 13.

Subsequently, the second address notification unit 123 of the second simulator 12 acquires, from the second simulation execution unit 122, information related to a second address of the first shared memory 13 in which the second data is stored. The second address notification unit 123 divides the information related to the second address of the first shared memory 13 into pieces of the size defined by the FMI standard, and transmits a second notification including the divided pieces of information related to the second address of the first shared memory 13 to the first address notification unit 113 of the first simulator 11 (step S106). The transmission of the second notification from the second address notification unit 123 to the first address notification unit 113 is executed by socket communication by using the second communication path via the connection bridge conforming to the FMI standard.

The second notification includes second communication standard information indicating the specific communication standard to which the second data conforms, in addition to the information related to the second address. The second address notification unit 123 also divides the second communication standard information into pieces of a size defined by the FMI standard similarly to the information related to the second address, and includes the divided pieces of second communication standard information in the second notification.

Subsequently, the first address notification unit 113 of the first simulator 11 receives the second notification by socket communication. The first address notification unit 113 combines the information related to the second address and the second communication standard information divided into pieces of the size defined by the FMI standard included in the second notification, and restores the information related to the second address and the second communication standard information. The first address notification unit 113 outputs the restored information related to the second address and the second communication standard information to the first simulation execution unit 112.

Subsequently, the first simulation execution unit 112 of the first simulator 11 receives the information related to the second address and the second communication standard information from the first address notification unit 113. The first simulation execution unit 112 determines a communication standard of the second data based on the second communication standard information. As a result, the first simulation execution unit 112 grasps a format according to the communication standard of the second data, that is, a data format of a communication frame related to the second data. The first simulation execution unit 112 outputs the information related to the second address and information on the format according to the communication standard of the second data to the first memory access control unit 111.

Subsequently, the first memory access control unit 111 of the first simulator 11 receives the information related to the second address and the information on the format according to the communication standard of the second data from the first simulation execution unit 112. The first memory access control unit 111 reads the second data from the first shared memory 13 based on the information related to the second address and the information on the format according to the communication standard of the second data (step S107). For example, in a case where the information related to the second address includes a head address of the second data and the information on the format according to the communication standard of the second data includes information related to a size of the second data, the first memory access control unit 111 can read data corresponding to the size of the second data from the head address of the second data from the first shared memory 13. In this way, the first simulator 11 acquires the second data from the second simulator 12 by using the second communication path including the first shared memory 13.

The first memory access control unit 111 outputs the read second data to the first simulation execution unit 112. The second data can be used for the simulation by the first simulation execution unit 112.

According to the first embodiment, data is transmitted and received between the first simulator 11 and the second simulator 12 by using both the first communication path and the second communication path. First, transmission and reception of data used in a co-simulation are performed by using the first communication path via the first shared memory 13. In the transmission and reception of data via the first shared memory 13, it is not necessary to perform data conversion processing for coping with the restriction of the FMI standard, and thus, it is not necessary to develop a connection bridge conforming to the FMI standard.

On the other hand, in the first embodiment, it is necessary to share the information related to the address of the first shared memory 13 in which the data to be transmitted and received is stored between the first simulator 11 and the second simulator 12. The information related to the address of the first shared memory 13 is transmitted and received by using the second communication path. Since a frame restricted by the FMI standard is used in the transmission and reception of the data using the communication path, it is necessary to develop a second connection bridge conforming to the FMI standard in the second communication path. However, since an amount of the information related to the address of the first shared memory 13 is smaller than an amount of the data transmitted and received via the first shared memory 13, a number of divisions of the information related to the address divided into the size according to the definition of the FMI standard is reduced. That is, since a number of data connection lines in the connection bridge conforming to the FMI standard can be reduced, development man-hours for constructing the connection bridge conforming to the FMI standard in the second communication path can be reduced.

In particular, when data (frame) is transmitted and received between the first simulator 11 and the second simulator 12 via the connection bridge conforming to the FMI standard, a number of divisions of a frame increases in a case where one frame is large. When the number of divisions increases, the number of data connection lines for transmitting and receiving the data increases in proportion to the number of divisions, and the development man-hours for the connection bridge conforming to the FMI standard also increase. However, according to the first embodiment, since the data transmitted and received via the connection bridge conforming to the FMI standard is the information of the address of the first shared memory 13, it is possible to prevent the development man-hours for the connection bridge conforming to the FMI standard from increasing depending on a size of one frame.

In addition, in a case where a frame of a communication protocol is divided and transmitted and received between the first simulator 11 and the second simulator 12, socket communication is repeatedly performed for the number of divisions. Therefore, the number of times of socket communication increases as the number of divisions of the frame increases. Because the socket communication is implemented in kernel space, it takes time for task switches. That is, as the number of divisions of the frame increases, the number of times of the socket communication increases, and as a result, an execution time of the co-simulation increases. However, according to the first embodiment, since the data transmitted and received via the connection bridge conforming to the FMI standard is the information of the address of the first shared memory 13, the number of divisions can be reduced, and the execution time of the co-simulation can be shortened.

### (Modification of First Embodiment)

Next, a modification of the first embodiment will be described. In the first embodiment described above, the simulator on the transmission side transmits the communication standard information for specifying the communication standard of the data stored in the first shared memory 13 to the simulator on the reception side, and the simulator on the reception side determines the communication standard of the data stored in the first shared memory 13 based on the communication standard information. On the other hand, in the modification of the first embodiment, transfer of the information related to the address of the first shared memory 13 in which the data is stored is performed through a dedicated communication path distinguished for each communication standard, so that the simulator on the reception side determines the communication standard of the data stored in the first shared memory 13.

FIG. 4 is a block diagram: illustrating an example of a configuration of a co-simulation apparatus la according to the modification of the first embodiment. In FIG. 4 according to the modification of the first embodiment, components having the same functions as those in FIG. 1 according to the first embodiment are denoted by the same reference numerals, and description thereof will be omitted.

As illustrated in FIG. 4, the co-simulation apparatus 1a includes a first simulator 11a, a second simulator 12a, and the first shared memory 13. The first simulator 11a includes a third address notification unit 114 in addition to the configuration of the first simulator 11 illustrated in FIG. 1. In addition, the first simulation execution unit 112 is changed to a first simulation execution unit 112a. The first simulation execution unit 112a is connected to the third address notification unit 114.

The second simulator 12a includes a fourth address notification unit 124 in addition to the configuration of the second simulator 12 illustrated in FIG. 1. The second simulation execution unit 122 is changed to a second simulation execution unit 122a. The second simulation execution unit 122a is connected to the fourth address notification unit 124. The third address notification unit 114 and the fourth address notification unit 124 are connected to each other via a third communication path via the connection bridge conforming to the FMI standard.

The third address notification unit 114 and the fourth address notification unit 124 transmit and receive a notification including information related to the address of the first shared memory 13 in which data used in the co-simulation is stored. The functions of the third address notification unit 114 and the fourth address notification unit 124 are the same as those of the first address notification unit 113 and the second address notification unit 123 in that the information related to the address of the first shared memory 13 is transmitted and received. However, in the co-simulation apparatus la according to the modification of the first embodiment, the address notification unit used for transmitting and receiving the information related to the address of the first shared memory 13 is different for each communication standard of data stored in the first shared memory 13.

In a case where the first address notification unit 113 and the second address notification unit 123 transmit and receive the information related to the address of the first shared memory 13 in which data in a format according to a first communication standard is stored via the second communication path, the third address notification unit 114 and the fourth address notification unit 124 transmit and receive the information related to the address of the first shared memory 13 in which data in a format according to a second communication standard different from the first communication standard is stored via the third communication path. As described above, in the co-simulation apparatus 1a according to the modification of the first embodiment, a dedicated communication path according to the communication standard of the data stored in the first shared memory 13 is provided in order to transmit and receive the information related to the address of the first shared memory 13. As a result, the simulator on the reception side can determine a communication standard related to the data stored in the first shared memory 13 based on the communication path that has received the information related to the address of the first shared memory 13.

Next, processing of the co-simulation apparatus 1a according to the modification of the first embodiment will be described. The first memory access control unit 111 stores first data, which is the data in the format according to the first communication standard, in the first shared memory 13. For example, the first communication standard is CAN. In addition, the first memory access control unit 111 stores third data, which is data in the format according to the second communication standard, in the first shared memory 13. For example, the second communication standard is Ethernet.

Subsequently, the first address notification unit 113 acquires, from the first simulation execution unit 112a, information related to the first address of the first shared memory 13 in which the first data is stored. The first address notification unit 113 divides the information related to the first address of the first shared memory 13 into pieces of the size defined by the FMI standard, and transmits a first notification including the divided pieces of information related to the first address of the first shared memory 13 to the second address notification unit 123 via the second communication path. At this time, the first notification does not include the first communication standard information indicating the first communication standard to which the first data conforms.

The third address notification unit 114 acquires, from the first simulation execution unit 112a, information related to a third address of the first shared memory 13 in which the third data is stored. The third address notification unit 114 divides the information related to the third address of the first shared memory 13 into pieces of the size defined by the FMI standard, and transmits a third notification including the divided pieces of information related to the third address of the first shared memory 13 to the fourth address notification unit 124 via the third communication path. At this time, the third notification does not include third communication standard information indicating the second communication standard to which the third data conforms.

Subsequently, the second address notification unit 123 receives the first notification by socket communication. The second address notification unit 123 combines the information related to the first address divided into pieces of the size defined by the FMI standard included in the first notification, and restores the information related to the first address. The second address notification unit 123 outputs the restored information related to the first address to the second simulation execution unit 122a.

The fourth address notification unit 124 receives the third notification by socket communication. The fourth address notification unit 124 combines the information related to the third address divided into pieces of the size defined by the FMI standard included in the third notification, and restores the information related to the third address. The fourth address notification unit 124 outputs the restored information related to the third address to the second simulation execution unit 122a.

Subsequently, the second simulation execution unit 122a receives the information related to the first address from the second address notification unit 123. The second simulation execution unit 122a determines that the first data is the data in the format according to the first communication standard based on the reception of the first notification including the information related to the first address from the second address notification unit 123 via the first communication path. The second simulation execution unit 122a outputs the information related to the first address and the information on the format according to the first communication standard of the first data to the second memory access control unit 121.

The second simulation execution unit 122a also receives the information related to the third address from the fourth address notification unit 124. The second simulation execution unit 122a determines that the third data is the data in the format according to the second communication standard based on the reception of the third notification including the information related to the third address from the fourth address notification unit 124 via the third communication path. The second simulation execution unit 122a outputs the information related to the third address and information on the format according to the second communication standard of the third data to the second memory access control unit 121.

Subsequently, the second memory access control unit 121 receives the information related to the first address and the information on the format according to the first communication standard of the first data from the second simulation execution unit 122a. The second memory access control unit 121 reads the first data from the first shared memory 13 based on the information related to the first address and the information on the format according to the first communication standard of the first data.

In addition, the second memory access control unit 121 receives the information related to the third address and the information on the format according to the second communication standard of the third data from the second simulation execution unit 122a. The second memory access control unit 121 reads the third data from the first shared memory 13 based on the information related to the third address and the information on the format according to the second communication standard of the third data.

In this way, the second simulator 12a acquires the first data and the third data from the first simulator 11a by using the first communication path including the first shared memory 13. The second memory access control unit 121 outputs the read first data and third data to the second simulation execution unit 122a. The second simulation execution unit 122a performs a simulation based on the first data and the third data.

According to the modification of the first embodiment, the information related to the address of the first shared memory 13 is transmitted and received by socket communication by using a different communication path according to the communication standard of the data transmitted and received via the first shared memory 13. In other words, in the modification of the first embodiment, a socket communication port according to a specific communication standard is used for transmission and reception of the information related to the address of the first shared memory 13. The simulator on the reception side can determine the communication standard related to the data stored in the first shared memory 13 based on the communication path that has received the information related to the address of the first shared memory 13. Therefore, the simulator on the transmission side does not need to transmit communication standard information for determining the communication standard of the data stored in the first shared memory 13 to the simulator on the reception side.

### Second Embodiment

Next, a second embodiment will be described. In the first embodiment, a co-simulation apparatus that executes a co-simulation in cooperation with two simulators implemented by a single computer has been described. On the other hand, in the second embodiment, a co-simulation apparatus that executes a co-simulation in cooperation with a simulator implemented by a different computer will be described.

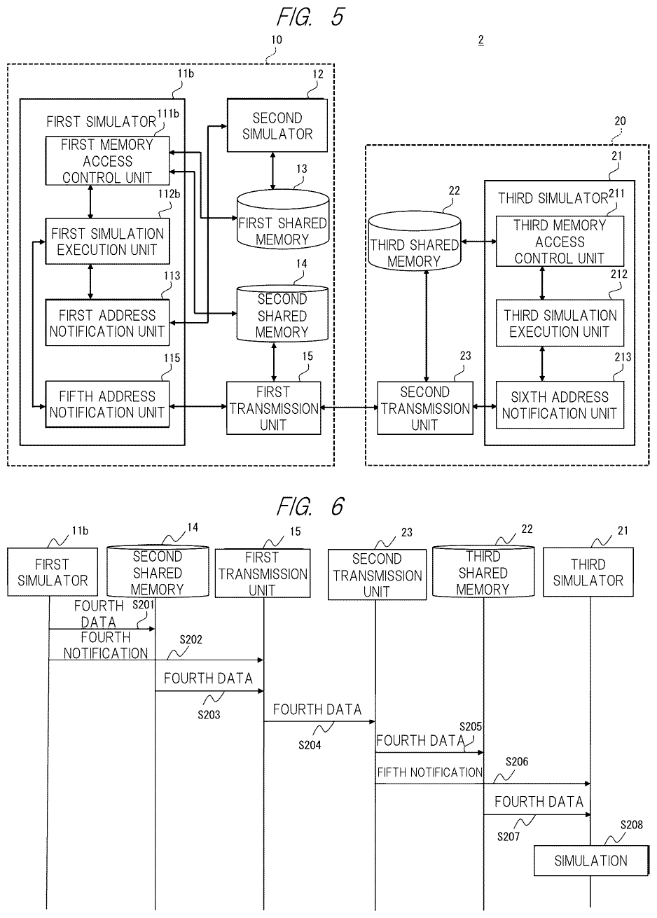

An example of a configuration of a co-simulation apparatus 2 according to the second embodiment will be described with reference to FIG. 5. FIG. 5 is a block diagram illustrating an example of a configuration of the co-simulation apparatus 2 according to the second embodiment. In FIG. 5 according to the second embodiment, components having the same functions as those in FIG. 1 according to the first embodiment are denoted by the same reference numerals, and the description thereof will be omitted.

As illustrated in FIG. 5, the co-simulation apparatus 2 according to the second embodiment includes a first simulator 11b, a second simulator 12, a third simulator 21, a first shared memory 13, a second shared memory 14, a third shared memory 22, a first transmission unit 15, and a second transmission unit 23. Furthermore, the co-simulation apparatus 2 includes a plurality of computers. In the example of FIG. 5, the co-simulation apparatus 2 includes a first computer 10 and a second computer 20. The hardware configuration of each of the first computer 10 and the second computer 20 may be similar to the hardware configuration illustrated in FIG. 2.

The first computer 10 includes the first simulator 11b, the second simulator 12, the first shared memory 13, the second shared memory 14, and the first transmission unit 15. The first simulator 11b, the second simulator 12, and the first transmission unit 15 are implemented by the first computer 10. For example, the first simulator 11b, the second simulator 12, and the first transmission unit 15 may be implemented by cooperation of one or more programs installed in the first computer 10 and hardware of a processor and a memory of the first computer 10. The first simulator 11b is connected to the second simulator 12, the first shared memory 13, the second shared memory 14, and the first transmission unit 15. The first shared memory 13 is connected to the second simulator 12. The second shared memory 14 is connected to the first transmission unit 15.

The second computer 20 includes the third simulator 21, the third shared memory 22, and the second transmission unit 23. The third simulator 21 and the second transmission unit 23 are implemented by the second computer 20. For example, the third simulator 21 and the second transmission unit 23 may be implemented by cooperation of one or more programs installed in the second computer 20 and hardware of a processor and a memory of the second computer 20. The third simulator 21 is connected to the third shared memory 22 and the second transmission unit 23. The second transmission unit 23 is connected to the third shared memory 22 and the first transmission unit 15.

The second shared memory 14 is an area that can be accessed by a plurality of processes in the memory of the first computer 10. Data stored in the second shared memory 14 may be transferred between the processes by using, for example, an API provided by an OS or the like.

The third shared memory 22 is an area that can be accessed by a plurality of processes in the memory of the second computer 20. Data stored in the third shared memory 22 may be transferred between the processes by using, for example, an API provided by an OS or the like.

As illustrated in FIG. 5, the first simulator 11b includes a fifth address notification unit 115 in addition to the configuration of the first simulator 11 illustrated in FIG. 1. In addition, the first memory access control unit 111 is changed to a first memory access control unit 111b, and the first simulation execution unit 112 is changed to a first simulation execution unit 112b. The first memory access control unit 111b is connected to the second shared memory 14. The fifth address notification unit 115 is connected to the first simulation execution unit 112b and the first transmission unit 15.

The third simulator 21 includes a third memory access control unit 211, a third simulation execution unit 212, and a sixth address notification unit 213. The third memory access control unit 211 is connected to the third shared memory 22 and the third simulation execution unit 212. The sixth address notification unit 213 is connected to the third simulation execution unit 212 and the second transmission unit 23.

The first memory access control unit 111b and the first transmission unit 15 write or read data used in a co-simulation to or from the second shared memory 14. The first simulator 11b and the first transmission unit 15 can transfer data via the second shared memory 14. A communication path connecting the first memory access control unit 111b of the first simulator 11b and the first transmission unit 15 via the second shared memory 14 corresponds to a fourth communication path.

The third memory access control unit 211 and the second transmission unit 23 write or read data used in the co-simulation to or from the third shared memory 22. The third simulator 21 and the second transmission unit 23 can transfer data via the third shared memory 22. A communication path connecting the third memory access control unit 211 of the third simulator 21 and the second transmission unit 23 via the third shared memory 22 corresponds to a fifth communication path.

The first simulation execution unit 112b and the third simulation execution unit 212 are implemented by different simulation tools, and execute different simulations. Since the co-simulation in which the first simulator 11b and the third simulator 21 operate in cooperation is executed in the co-simulation apparatus 2, the first simulator 11b and the third simulator 21 transmit and receive data used in a simulation.

Specifically, the first simulation execution unit 112b of the first simulator 11b receives data from the third simulator 21 via the third shared memory 22, the second transmission unit 23, the first transmission unit 15, and the second shared memory 14, and executes a simulation using the data. In addition, the first simulation execution unit 112b generates data by executing the simulation, and stores the generated data in the second shared memory 14 via the first memory access control unit 111b so that the data can be used in the simulation executed by the third simulator 21.

The third simulation execution unit 212 of the third simulator 21 receives data from the first simulator 11b via the second shared memory 14, the first transmission unit 15, the second transmission unit 23, and the third shared memory 22, and executes a simulation using the data. In addition, the third simulation execution unit 212 generates data by executing the simulation, and stores the generated data in the third shared memory 22 via the third memory access control unit 211 so that the data can be used in the simulation executed by the first simulator 11b.

The fifth address notification unit 115 and the first transmission unit 15 transmit and receive a notification including information related to an address (memory address) of the second shared memory 14 in which data used in a co-simulation is stored. A communication path connecting the fifth address notification unit 115 of the first simulator 11b and the first transmission unit 15 by socket communication corresponds to a sixth communication path via the connection bridge conforming to the FMI standard.

In a case where the information related to the address of the second shared memory 14 is transmitted and received by using the sixth communication path, the fifth address notification unit 115 or the first transmission unit 15 on the transmission side divides the information related to the address into pieces of the size defined by the FMI standard, and transmits the divided pieces of information related to the address to the fifth address notification unit 115 or the first transmission unit 15 on the reception side by socket communication. The fifth address notification unit 115 or the first transmission unit 15 on the reception side receives the information related to the address divided into pieces of the size defined by the FMI standard by socket communication, combines the divided pieces of information related to the address, and restores the information related to the address of the second shared memory 14. The first simulator 11b including the fifth address notification unit 115 or the first transmission unit 15 on the reception side can acquire data stored in the second shared memory 14 by using the restored information related to the address.

The sixth address notification unit 213 and the second transmission unit 23 transmit and receive a notification including information related to an address (memory address) of the third shared memory 22 in which the data used in the co-simulation is stored. A communication path connecting the sixth address notification unit 213 of the third simulator 21 and the second transmission unit 23 by socket communication corresponds to a seventh communication path via the connection bridge conforming to the FMI standard.

In a case where the information related to the address of the third shared memory 22 is transmitted and received by using the seventh communication path, the sixth address notification unit 213 or the second transmission unit 23 on the transmission side divides the information related to the address into pieces of the size defined by the FMI standard, and transmits the divided pieces of information related to the address to the sixth address notification unit 213 or the second transmission unit 23 on the reception side by socket communication. The sixth address notification unit 213 or the second transmission unit 23 on the reception side receives the information related to the address divided into pieces of the size defined by the FMI standard by socket communication, combines the divided pieces of information related to the address, and restores the information related to the address of the third shared memory 22. The third simulator 21 including the sixth address notification unit 213 or the second transmission unit 23 on the reception side can acquire data stored in the third shared memory 22 by using the restored information related to the address.

In addition, the first transmission unit 15 and the second transmission unit 23 transmit and receive the data used in the co-simulation by socket communication. A communication path connecting the first transmission unit 15 and the second transmission unit 23 by socket communication corresponds to an eighth communication path via the connection bridge conforming to the FMI standard.

The first transmission unit 15 divides the data read from the second shared memory 14 into pieces of the size defined by the FMI standard, and transmits the divided pieces of data to the second transmission unit 23 by socket communication. The second transmission unit 23 receives the data divided into pieces of the size defined by the FMI standard by socket communication, and restores the data by combining the divided pieces of data. The second transmission unit 23 stores the restored data in the third shared memory 22.

The second transmission unit 23 divides the data read from the third shared memory 22 into pieces of the size defined by the FMI standard, and transmits the divided pieces of data to the first transmission unit 15 by socket communication. The first transmission unit 15 receives the data divided into pieces of the size defined by the FMI standard by socket communication, and restores the data by combining the divided pieces of data. The first transmission unit 15 stores the restored data in the second shared memory 14.

Next, processing of the co-simulation apparatus 2 according to the second embodiment will be described with reference to FIG. 6. FIG. 6 is a sequence diagram illustrating an example of the processing of the co-simulation apparatus 2 according to the second embodiment. Note that FIG. 6 illustrates processing in which the third simulator 21 performs a simulation by using data provided from the first simulator 11b in a co-simulation in which the first simulator 11b implemented by the first computer 10 and the third simulator 21 implemented by the second computer 20 operate in cooperation.

First, in step S201, the first memory access control unit 111b of the first simulator 11b stores fourth data, which is data in a format according to a specific communication standard, in the second shared memory 14. Here, the fourth data may be, for example, data obtained by the simulation by the first simulation execution unit 112b of the first simulator 11b.

Subsequently, the fifth address notification unit 115 of the first simulator 11b acquires, from the first simulation execution unit 112b, information related to a fourth address of the second shared memory 14 in which the fourth data is stored. The fifth address notification unit 115 divides the information related to the fourth address of the second shared memory 14 into pieces of the size defined by the FMI standard, and transmits a fourth notification including the divided pieces of information related to the fourth address of the second shared memory 14 to the first transmission unit 15 (step S202). As described above, the communication path between the fifth address notification unit 115 and the first transmission unit 15 is the sixth communication path via the connection bridge conforming to the FMI standard. That is, the fifth address notification unit 115 transmits the fourth notification to the first transmission unit 15 by socket communication which is a method for interprocess communication using the sixth communication path via the connection bridge conforming to the FMI standard.

The fourth notification includes fourth communication standard information indicating the specific communication standard to which the fourth data conforms, in addition to the information related to the fourth address. The fifth address notification unit 115 also divides the fourth communication standard information into pieces of the size defined by the FMI standard similarly to the information related to the fourth address, and includes the divided pieces of fourth communication standard information in the fourth notification.

Subsequently, the first transmission unit 15 receives the fourth notification by socket communication. The first transmission unit 15 combines the information related to the fourth address and the fourth communication standard information divided into pieces of the size defined by the FMI standard included in the fourth notification, and restores the information related to the fourth address and the fourth communication standard information. The first transmission unit 15 determines a communication standard of the fourth data based on the restored fourth communication standard information, and grasps information on a format according to the communication standard of the fourth data. The first transmission unit 15 reads the fourth data from the second shared memory 14 based on the information related to the fourth address and the information on the format according to the communication standard of the fourth data (step S203). In this way, the first transmission unit 15 acquires the fourth data from the first simulator 11b by using the fourth communication path including the second shared memory 14.

Subsequently, the first transmission unit 15 divides the fourth data and the fourth communication standard information into pieces of the size defined by the FMI standard, and transmits the divided fourth data and fourth communication standard information to the second transmission unit 23 by socket communication via the eighth communication path via the connection bridge conforming to the FMI standard (step S204).

Subsequently, the second transmission unit 23 receives the divided fourth data and fourth communication standard information by socket communication. The second transmission unit 23 combines the fourth data and the fourth communication standard information divided into pieces of the size defined by the FMI standard to restore the fourth data and the fourth communication standard information. The second transmission unit 23 stores the restored fourth data in the third shared memory 22 (step S205).

In addition, the second transmission unit 23 divides information related to a fifth address of the third shared memory 22 in which the fourth data is stored into pieces of the size defined by the FMI standard, and transmits a fifth notification including the divided pieces of information related to the fifth address of the third shared memory 22 to the sixth address notification unit 213 of the third simulator 21 (step S206). As described above, the communication path between the second transmission unit 23 and the sixth address notification unit 213 is the seventh communication path via the connection bridge conforming to the FMI standard. That is, the second transmission unit 23 transmits the fifth notification to the sixth address notification unit 213 by socket communication which is a method for interprocess communication using the seventh communication path via the connection bridge conforming to the FMI standard.

The fifth notification includes the fourth communication standard information in addition to the information related to the fifth address. The second transmission unit 23 also divides the fourth communication standard information into pieces of the size defined by the FMI standard similarly to the information related to the fifth address, and includes the divided pieces of fourth communication standard information in the fifth notification.

Subsequently, the sixth address notification unit 213 of the third simulator 21 receives the fifth notification by socket communication. The sixth address notification unit 213 combines the information related to the fifth address and the fourth communication standard information divided into pieces of the size defined by the FMI standard included in the fifth notification, and restores the information related to the fifth address and the fourth communication standard information. The sixth address notification unit 213 outputs the restored information related to the fifth address and the fourth communication standard information to the third simulation execution unit 212.

Subsequently, the third simulation execution unit 212 of the third simulator 21 receives the information related to the fifth address and the fourth communication standard information from the sixth address notification unit 213. The third simulation execution unit 212 determines a communication standard of the fourth data based on the fourth communication standard information. As a result, the third simulation execution unit 212 grasps information on a format according to the communication standard of the fourth data. The third simulation execution unit 212 outputs the information related to the fifth address and the information on the format according to the communication standard of the fourth data to the third memory access control unit 211.

Subsequently, the third memory access control unit 211 of the third simulator 21 receives the information related to the fifth address and the information on the format according to the communication standard of the fourth data from the third simulation execution unit 212. The third memory access control unit 211 reads the fourth data from the third shared memory 22 based on the information related to the fourth address and the information on the format according to the communication standard of the fourth data (step S207). In this way, the third simulator 21 acquires the fourth data from the second transmission unit 23 by using the fifth communication path including the third shared memory 22. In addition, the third memory access control unit 211 outputs the read fourth data to the third simulation execution unit 212.

Subsequently, the third simulation execution unit 212 of the third simulator 21 performs a simulation based on the fourth data (step S208). The third simulation execution unit 212 generates fifth data conforming to a specific communication standard as a simulation result. Here, the communication standard of the fifth data may be the same as the communication standard to which the fourth data conforms.

When the first simulator 11b executes the simulation by using the fifth data, the third simulator 21 transmits the fifth data to the first simulator 11b via the third shared memory 22, the second transmission unit 23, the first transmission unit 15, and the second shared memory 14. A path for transmitting data from the third simulator 21 to the first simulator 11b is opposite to a path for transmitting data from the first simulator 11b to the third simulator 21. However, since a similar method can be used as the data transmission method, the description thereof will be omitted.

According to the second embodiment, data is transmitted and received between the first simulator 11b implemented by the first computer 10 and the third simulator 21 implemented by the second computer 20 via the first transmission unit 15 and the second transmission unit 23. As a result, even in a case where a plurality of simulators straddle a plurality of computers, it is possible to execute a co-simulation in which the plurality of simulators operate in cooperation as in the first embodiment.

In the first computer 10, the first simulator 11b and the first transmission unit 15 transmit and receive data by using both the fourth communication path and the sixth communication path. In the second computer 20, the third simulator 21 and the second transmission unit 23 transmit and receive data by using both the fifth communication path and the seventh communication path. In the fourth communication path including the second shared memory 14 and the fifth communication path including the third shared memory 22, it is not necessary to develop a connection bridge conforming to the FMI standard.

On the other hand, in the sixth communication path and the seventh communication path, it is necessary to develop a connection bridge conforming to the FMI standard. However, since the information related to the addresses of the second shared memory 14 and the third shared memory 22 is smaller than data transmitted and received via the second shared memory 14 and the third shared memory 22, development man-hours for the connection bridge conforming to the FMI standard in the sixth communication path and the seventh communication path are small. In addition, since an amount of data transmitted and received via the connection bridge conforming to the FMI standard can be suppressed, an execution time of a co-simulation can be shortened. As described above, the co-simulation apparatus 2 according to the second embodiment can obtain the same effects as those of the co-simulation apparatus according to the first embodiment.

In the second embodiment, it has been described that the first computer 10 includes the first shared memory 13 and the second shared memory 14, but the first computer 10 may include only the first shared memory 13. In this case, the first transmission unit 15 is connected to the first shared memory 13. That is, the fourth communication path is a path connected from the first memory access control unit 111b to the first transmission unit 15 via the first shared memory 13.

In the second embodiment, the example in which the communication standard of the fourth data is determined based on the fourth communication standard information has been described. However, as in the modification of the first embodiment, the communication standard of the fourth data may be determined by using a different communication path according to the communication standard of data to be transmitted and received. In this case, since a socket communication port according to a specific communication standard is used in the transmission and reception of data of each of the sixth to eighth communication paths, it is not necessary to transmit and receive the fourth communication standard information.

In the first embodiment and the modification of the first embodiment, the co-simulation apparatuses 1 and 1a including two simulators are illustrated, and in the second embodiment, the co-simulation apparatus 2 including three simulators is illustrated, but the number of simulators is not limited to the illustrated number. For example, in the co-simulation apparatus 2 according to the second embodiment, three or more simulators may be included on the first computer 10 side, and two or more simulators may be included on the second computer 20 side. Since this disclosure can be applied to transmission and reception of data between simulators, the larger the number of simulators, the more remarkable the effect achieved by this disclosure.

Although this disclosure has been described with reference to the embodiments, this disclosure is not limited to the above-described embodiments. Various modifications that can be understood by those skilled in the art can be made to the configuration and details of this disclosure within the scope of this disclosure. Each embodiment can be appropriately combined with another embodiment.

What is claimed is:

1. A non-transitory computer readable medium storing a program for causing a co-simulation apparatus including a first simulator, a second simulator different from the first simulator, a first communication path for transmitting and receiving data between the first simulator and the second simulator via a shared memory, and a second communication path for transmitting and receiving data between the first simulator and the second simulator by socket communication to execute a co-simulation method, the co-simulation method comprising:
by the first simulator,
storing first data in a format according to a specific communication standard in the shared memory via the first communication path,
dividing information related to a first address of the shared memory in which the first data is stored into pieces of a size defined by a functional mock-up interface (FMI) standard, and
transmitting a first notification including the divided pieces of information related to the first address of the shared memory to the second simulator via the second communication path; and
by the second simulator,
receiving the first notification via the second communication path,
combining the divided pieces of information related to the first address included in the first notification to restore the information related to the first address, and
reading the first data stored in the shared memory via the first communication path by using the restored information related to the first address.

2. The non-transitory computer readable medium according to claim 1,
wherein the co-simulation method further comprises:
by the second simulator,
generating second data in the format according to the specific communication standard by performing a simulation based on the read first data,
storing the generated second data in the shared memory via the first communication path,
dividing information related to a second address of the shared memory in which the second data is stored into pieces of the size defined by the FMI standard, and
transmitting a second notification including the divided pieces of information related to the second address of the shared memory to the first simulator via the second communication path; and
by the first simulator,
receiving the second notification via the second communication path,
combining the divided pieces of information related to the second address included in the second notification to restore the information related to the second address, and
reading the second data stored in the shared memory via the first communication path by using the restored information related to the second address.

3. The non-transitory computer readable medium according to claim 1,
wherein the co-simulation method further comprises:
by the first simulator,
dividing communication standard information indicating the specific communication standard into pieces of the size defined by the FMI standard, and
including the divided pieces of communication standard information in the first notification; and
by the second simulator,
combining the divided communication standard information included in the first notification to restore the communication standard information, and
determining a communication standard of the first data based on the restored communication standard information.

4. The non-transitory computer readable medium according to claim 1,
wherein the specific communication standard is a first communication standard, and
wherein the co-simulation apparatus further includes a third communication path for transmitting and receiving data by socket communication, and the co-simulation method further comprises:
by the first simulator,
storing third data in a format according to a second communication standard different from the first communication standard in the shared memory via the first communication path,
dividing information related to a third address of the shared memory in which the third data is stored into pieces of the size defined by the FMI standard, and
transmitting a third notification including the divided pieces of information related to the third address of the shared memory to the second simulator via the third communication path; and
by the second simulator,
receiving the third notification via the third communication path,
combining the divided pieces of information related to the third address included in the third notification to restore the information related to the third address, and
reading the third data stored in the shared memory via the first communication path by using the restored information related to the third address.

5. The non-transitory computer readable medium according to claim 4,
wherein the co-simulation method further comprises:
by the second simulator,
determining that the first data is data in the format according to the first communication standard based on reception of the first notification via the second communication path, and
determining that the third data is data in a format according to the second communication standard based on reception of the third notification via the third communication path.

6. The non-transitory computer readable medium according to claim 1,
wherein the specific communication standard is any of controller area network (CAN), Ethernet, CAN with flexible data rate (CAN FD), and FlexRay.

7. The non-transitory computer readable medium according to claim 1,
wherein the first simulator is an execution environment of model in the loop simulation (MILS), and
wherein the second simulator is an execution environment of simulator based processor in the loop simulation (SPILS) or software in the loop simulation (SILS).

8. The non-transitory computer readable medium according to claim 1,
wherein the first simulator is an execution environment of software in the loop simulation (SILS), and
wherein the second simulator is an execution environment of processor in the loop simulation (PILS).

9. The non-transitory computer readable medium according to claim 1,
wherein the first simulator and the second simulator are implemented by a single computer.

10. The non-transitory computer readable medium according to claim 1,
wherein the shared memory is a first shared memory, and
wherein the co-simulation apparatus further includes a third simulator, a first transmission unit, a second transmission unit, a fourth communication path for transmitting and receiving data between the first simulator and the first transmission unit via a second shared memory, a fifth communication path for transmitting and receiving data between the third simulator and the second transmission unit via a third shared memory, a sixth communication path for transmitting and receiving data between the first simulator and the first transmission unit by socket communication, a seventh communication path for transmitting and receiving data between the third simulator and the second transmission unit by socket communication, and an eighth communication path for transmitting and receiving data between the first transmission unit and the second transmission unit by socket communication, and the co-simulation method further comprises:
by the first simulator,
storing fourth data in a format according to a specific communication standard in the second shared memory via the fourth communication path,
dividing information related to a fourth address of the second shared memory in which the fourth data is stored into pieces of the size defined by the FMI standard, and
transmitting a fourth notification including the divided pieces of information related to the fourth address of the second shared memory to the first transmission unit via the sixth communication path;
by the first transmission unit,
receiving the fourth notification via the sixth communication path,
combining the divided pieces of information related to the fourth address included in the fourth notification to restore the information related to the fourth address,
reading the fourth data stored in the second shared memory via the fourth communication path by using the restored information related to the fourth address,
dividing the read fourth data into the size defined by the FMI standard, and
transmitting the divided pieces of fourth data to the second transmission unit via the eighth communication path;
by the second transmission unit,
receiving the divided pieces of fourth data via the eighth communication path,
combining the divided pieces of fourth data to restore the fourth data,
storing the restored fourth data in the third shared memory via the fifth communication path,
dividing information related to a fifth address of the third shared memory in which the fourth data is stored into pieces of the size defined by the FMI standard, and
transmitting a fifth notification including the divided information related to the fifth address of the third shared memory to the third simulator via the seventh communication path; and
by the third simulator,
receiving the fifth notification via the seventh communication path,
combining the divided pieces of information related to the fifth address included in the fifth notification to restore the information related to the fifth address, and
reading the fourth data stored in the third shared memory via the fifth communication path by using the restored information related to the fifth address.

11. The non-transitory computer readable medium according to claim 10,
wherein the co-simulation apparatus includes a first computer and a second computer,
wherein the first simulator and the second simulator are implemented by the first computer, and
wherein the third simulator is implemented by the second computer.

12. A co-simulation method executed in a co-simulation apparatus including a first simulator, a second simulator different from the first simulator, a first communication path for transmitting and receiving data between the first simulator and the second simulator via a shared memory, and a second communication path for transmitting and receiving data between the first simulator and the second simulator by socket communication, the co-simulation method comprising:
by the first simulator,
storing first data in a format according to a specific communication standard in the shared memory via the first communication path,
dividing information related to a first address of the shared memory in which the first data is stored into pieces of a size defined by an FMI standard, and
transmitting a first notification including the divided pieces of information related to the first address of the shared memory to the second simulator via the second communication path; and
by the second simulator,
receiving the first notification via the second communication path,
combining the divided pieces of information related to the first address included in the first notification to restore the information related to the first address, and
reading the first data stored in the shared memory via the first communication path by using the restored information related to the first address.

13. The co-simulation method according to claim 12, further comprising:
by the second simulator,
generating second data in the format according to the specific communication standard by performing a simulation based on the read first data,
storing the generated second data in the shared memory via the first communication path,
dividing information related to a second address of the shared memory in which the second data is stored into pieces of the size defined by the FMI standard, and
transmitting a second notification including the divided pieces of information related to the second address of the shared memory to the first simulator via the second communication path; and
by the first simulator,
receiving the second notification via the second communication path,
combining the divided pieces of information related to the second address included in the second notification to restore the information related to the second address, and
reading the second data stored in the shared memory via the first communication path by using the restored information related to the second address.

14. The co-simulation method according to claim 12, further comprising:
by the first simulator,
dividing communication standard information indicating the specific communication standard into pieces of the size defined by the FMI standard, and
including the divided pieces of communication standard information in the first notification; and
by the second simulator,
combining the divided pieces of communication standard information included in the first notification to restore the communication standard information, and
determining a communication standard of the first data based on the restored communication standard information.

15. The co-simulation method according to claim 12,
wherein the specific communication standard is a first communication standard, and
wherein the co-simulation apparatus further includes a third communication path for transmitting and receiving data by socket communication, and the co-simulation method further comprising:
by the first simulator,
storing third data in a format according to a second communication standard different from the first communication standard in the shared memory via the first communication path,
dividing information related to a third address of the shared memory in which the third data is stored into pieces of the size defined by the FMI standard, and
transmitting a third notification including the divided pieces of information related to the third address of the shared memory to the second simulator via the third communication path; and
by the second simulator,
receiving the third notification via the third communication path,
combining the divided pieces of information related to the third address included in the third notification to restore the information related to the third address, and
reading the third data stored in the shared memory via the first communication path by using the restored information related to the third address.

16. The co-simulation method according to claim 15, further comprising:
by the second simulator,
determining that the first data is data in a format according to the first communication standard based on reception of the first notification via the second communication path, and
determining that the third data is data in the format according to the second communication standard based on reception of the third notification via the third communication path.

17. A co-simulation apparatus comprising:
a first simulator;
a second simulator different from the first simulator;
a shared memory;
a first communication path for transmitting and receiving data between the first simulator and the second simulator via the shared memory; and
a second communication path for transmitting and receiving data between the first simulator and the second simulator by socket communication,
wherein the first simulator
stores first data in a format according to a specific communication standard in the shared memory via the first communication path,
divides information related to a first address of the shared memory in which the first data is stored into pieces of a size defined by an FMI standard, and
transmits a first notification including the divided pieces of information related to the first address of the shared memory to the second simulator via the second communication path, and
wherein the second simulator
receives the first notification via the second communication path,
combines the divided pieces of information related to the first address included in the first notification to restore the information related to the first address, and
reads the first data stored in the shared memory via the first communication path by using the restored information related to the first address.

18. The co-simulation apparatus according to claim 17,
wherein the second simulator
generates second data in the format according to the specific communication standard by performing a simulation based on the read first data,
stores the generated second data in the shared memory via the first communication path,
divides information related to a second address of the shared memory in which the second data is stored into pieces of the size defined by the FMI standard, and
transmits a second notification including the divided pieces of information related to the second address of the shared memory to the first simulator via the second communication path, and
wherein the first simulator
receives the second notification via the second communication path,
combines the divided pieces of information related to the second address included in the second notification to restore the information related to the second address, and
reads the second data stored in the shared memory via the first communication path by using the restored information related to the second address.

19. The co-simulation apparatus according to claim 17,
wherein the first simulator
divides communication standard information indicating the specific communication standard into pieces of the size defined by the FMI standard, and
includes the divided pieces of communication standard information in the first notification, and
wherein the second simulator
combines the divided pieces of communication standard information included in the first notification to restore the communication standard information, and
determines a communication standard of the first data based on the restored communication standard information.

20. The co-simulation apparatus according to claim 17,
wherein the specific communication standard is a first communication standard,
wherein the co-simulation apparatus further comprises a third communication path for transmitting and receiving data by socket communication,
wherein the first simulator
stores third data in a format according to a second communication standard different from the first communication standard in the shared memory via the first communication path,
divides information related to a third address of the shared memory in which the third data is stored into pieces of the size defined by the FMI standard, and
transmits a third notification including the divided pieces of information related to the third address of the shared memory to the second simulator via the third communication path, and
wherein the second simulator
receives the third notification via the third communication path,
combines the divided pieces of information related to the third address included in the third notification to restore the information related to the third address,
reads the third data stored in the shared memory via the first communication path by using the restored information related to the third address,
determines that the first data is data in a format according to the first communication standard based on reception of the first notification via the second communication path, and
determines that the third data is data in the format according to the second communication standard based on reception of the third notification via the third communication path.
